(19) United States
(12) Patent Application Publication
(10) Pub. No.: US 2014/0184231 A1
(43) Pub. Date: Jul. 3, 2014

(54) TEST SYSTEM FOR A DOME SWITCH

(71) Applicant: UNIVERSAL CEMENT CORPORATION, Taipei City (TW)

(72) Inventors: Yann-Cherng CHERN, Taipei City (TW); Chih-Sheng HOU, Taipei City (TW)

(73) Assignee: UNIVERSAL CEMENT CORPORATION, Taipei City (TW)

(21) Appl. No.: 13/731,433

(22) Filed: Dec. 31, 2012

(51) Int. Cl. G01R 31/327

(52) U.S. Cl. CPC G01R 31/327
USPC 324/415

(57) ABSTRACT

A test system having a piece of film type pressure sensor configured under a dome switch for collecting a physical parameter selected from a group consisted of Actuation Force (AF), Timing T1, Contact Force (CF), Timing T2, On-Force (OF), Snap Ratio, and Key Journey of the dome switch is provided to facilitate product sorting according to one of the parameters.

### BACKGROUND

1. Technical Field

The present invention relates to a test system having a piece of film type pressure sensor for collecting a physical parameter selected from a group consisted of Actuation Force (AF), Timing T1, Contact Force (CF), Timing T2, On-Force (OF), Snap Ratio, and Key Journey of a dome switch, to facilitate product sorting according to one of the parameters.

2. Description of Related Art

FIG. 1 is a prior art test system

FIG. 1 shows a prior art test system shown in CN2525496. It disclosed a test system for testing forces of a key switch 16. A complex pressure mechanism 99 is adopted in the traditional test system. A push rod 990 is configured under the pressure mechanism 99 to provide a downward pressure against one of the keys 16 sequentially. The complex pressure mechanism 99 is electrically coupled to a control circuit 14; the control circuit 14 is then electrically coupled to a data output device 15 for outputting physical parameters sensed by the control circuit 14 through the feedback of the complex pressure mechanism 99.

FIG. 2 is a section view of a key switch in FIG. 1

FIG. 2 shows the structure of a key switch 16, each of which has a plastic key cap 162 configured on top. Each dome switch 100 further includes a membrane switch 13 and a rubber dome 120; the rubber dome 120 is configured on a top surface of the membrane switch 13. The membrane switch 13 has a top substrate 13T and a bottom substrate 13B; a spacer 134 is configured between the top substrate 13T and the bottom substrate 13B. A top electrode 131 is configured on the bottom surface of the top substrate 13T; a bottom electrode 132 aligned with the top electrode 131 is configured on a top surface of the bottom substrate 13B. A gap 133 is maintained between the top electrode 131 and the bottom electrode 132. A turn-on signal is triggered when the top electrode 131 contacts the bottom electrode 132. The rubber dome 120 includes a dome base 121, a dome wall 122, and a dome top 123. The dome top 123 is strengthened to withstand a pressure from the key cap 162 and the dome wall 122 is able to transfer the pressure downward against the membrane switch 13.

FIG. 3 is a rubber dome switch in a keyboard

FIG. 3 shows a rubber dome switch configured in a keyboard with plastic key caps 162 stripped off from top. A plurality of rubber dome 120 is configured on a piece of a dome base 121. A piece of membrane switch 13 is configured under the dome base 121; a turn-on signal shall be triggered when each of the rubber domes 120 is pressed down to the bottom. A key tray 11 is configured on the bottom to house the membrane switch 13, dome base 121, and the rubber dome 120.

### BRIEF DESCRIPTION OF THE DRAWINGS

The drawing includes several embodiments for the present invention, FIGS. 1-3 describes testing for a prior art; FIGS. 4-9 describes testing for a rubber dome switch; FIGS. 10-12 describes testing for a rubber dome; FIGS. 13-15 describes testing for a membrane switch; FIGS. 16-19 describes testing for a metal dome switch; and FIGS. 20-22 describes a metal dome.

FIG. 1 is a prior art test system

FIG. 2 is a section view of a key switch of FIG. 1

FIG. 3 is a rubber dome switch in a keyboard

FIG. 4-8 is a first embodiment according to the present invention

FIGS. 9A˜9D is a key switch array to be tested by the test system according to the present invention.

FIGS. 10˜12 is a second embodiment according to the present invention.

FIGS. 13˜15 is a third embodiment according to the present invention.

FIGS. 16˜19 show a fourth embodiment according to the present invention

FIGS. 20˜22 is a fifth embodiment according to the present invention

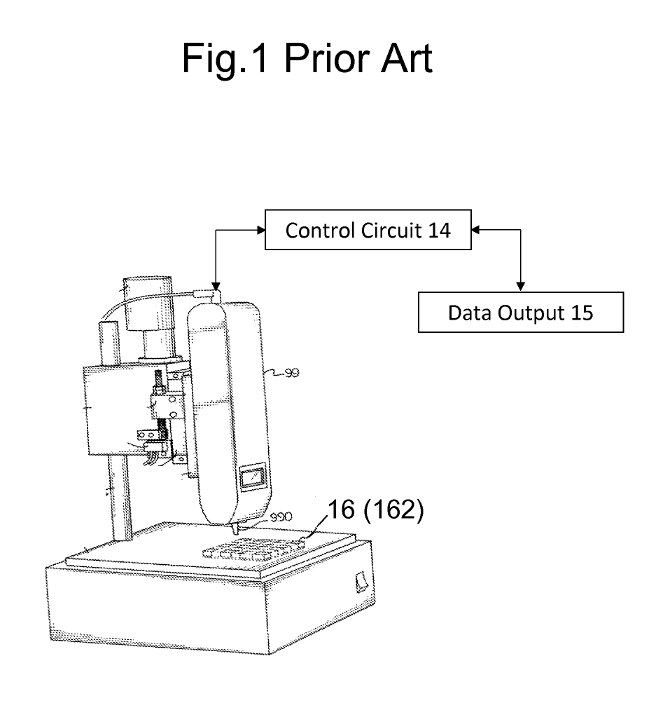

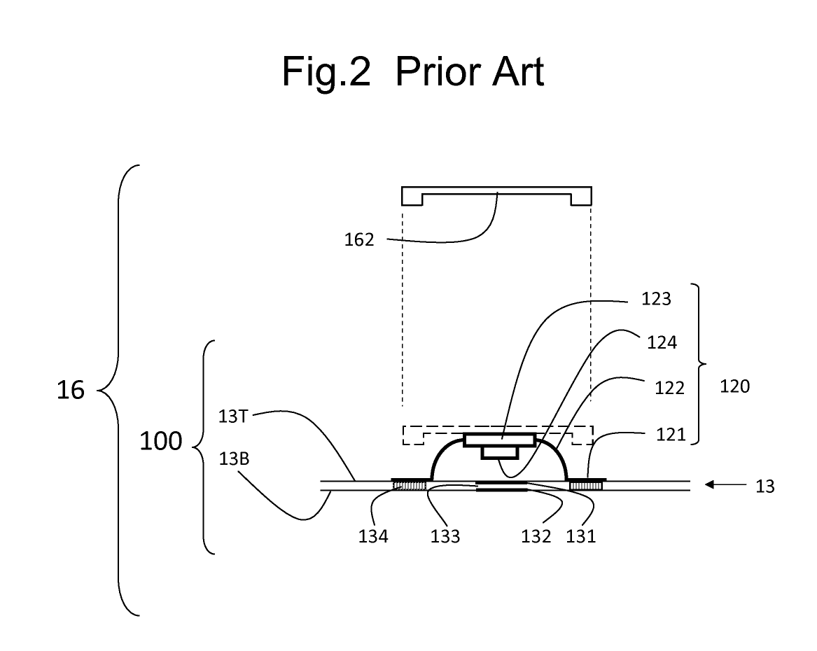

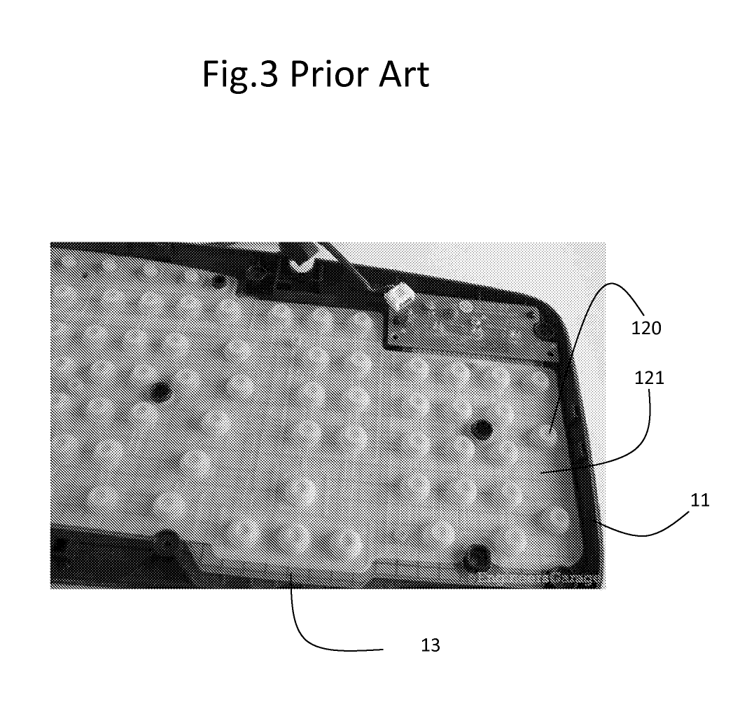

### DETAILED DESCRIPTION OF THE INVENTION

This invention uses a simple push rod as the pressure source for testing a dome switch or a key switch, with a plastic circuit board underlaid. A piece of pressure sensor is configured under the dome switch for sensing the changes of the pressure from top. A control circuit receives pressure data sensed by the underlaid pressure sensor for output or further processing before output. A simple structure and more convenient testing system is disclosed for testing a dome switch or an array of dome switches, either of which has a circuit board on the bottom.

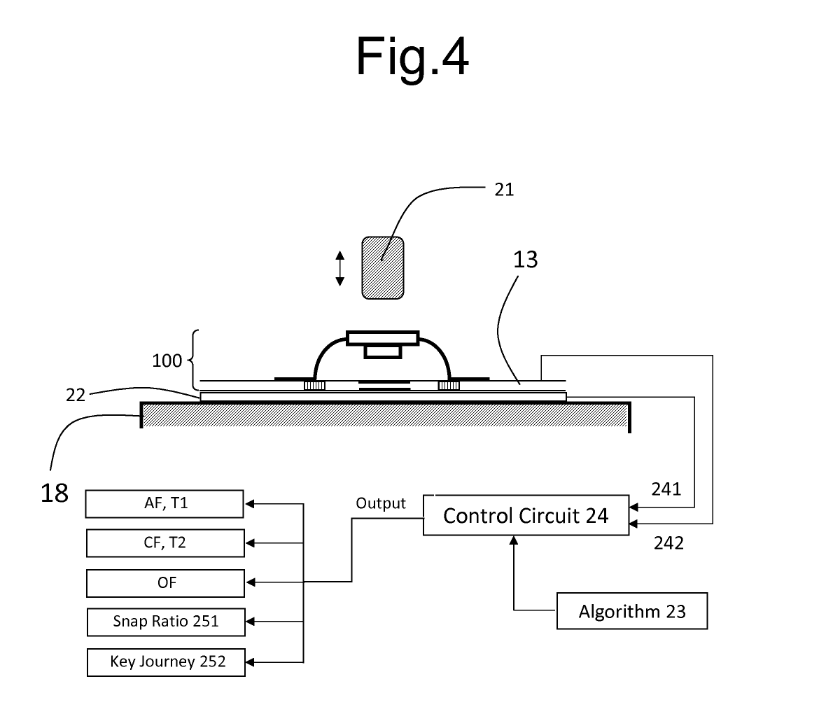

FIG. 4-9 is a first embodiment according to the present invention

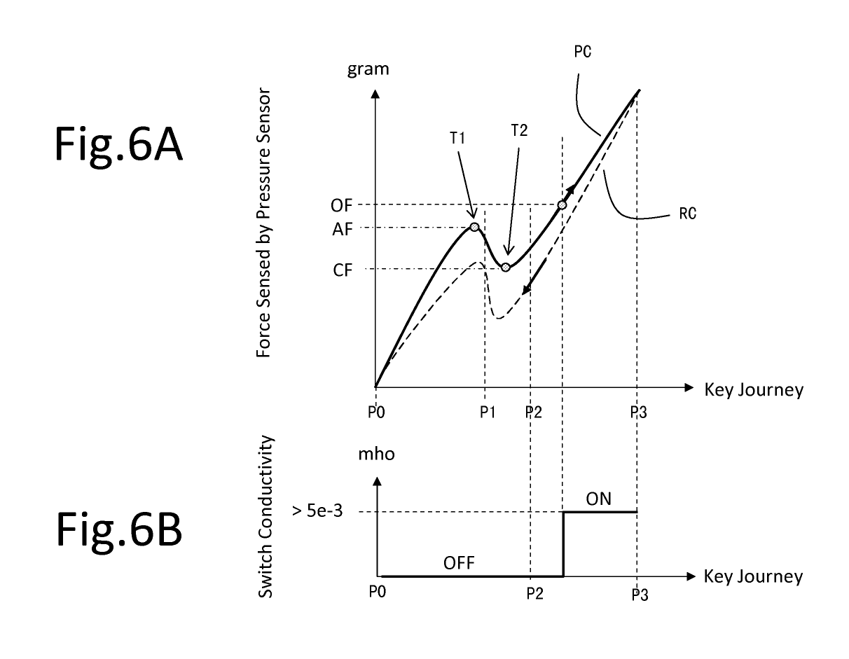

FIG. 4 shows a test system for testing a dome switch 100. The test system has a film type pressure sensor 22 which provides a top surface for carrying the dome switch 100 to be tested. A platform 18 is provided for carrying the film type pressure sensor 22. A control circuit 24 has a first end 241 electrically coupled to the film type pressure sensor 22 for sensing pressure. The control circuit 24 has a second end 242 electrically coupled to the membrane switch 13 of the dome switch 100. The control circuit 24 is able to detect a physical parameter selected from a group consisted of Actuation Force (AF), Timing T1, Contact Force (CF), Timing T2, and On-Force (OF), for the dome switch 100 when a pressure is applied onto the dome switch 100. A simple push rod 21 is configured above the dome switch 100 for providing such a pressure downward against the dome switch 100. An algorithm 23 is executed by control circuit 24 for the testing process. At least one of the physical parameters consisted of AF, T1, CF, T2, OF, Snap Ratio 251, and Key Journey 252, is output from the test system. The Snap Ratio 251 and Key Journey 252 shall be defined later in the description of FIG. 6B.

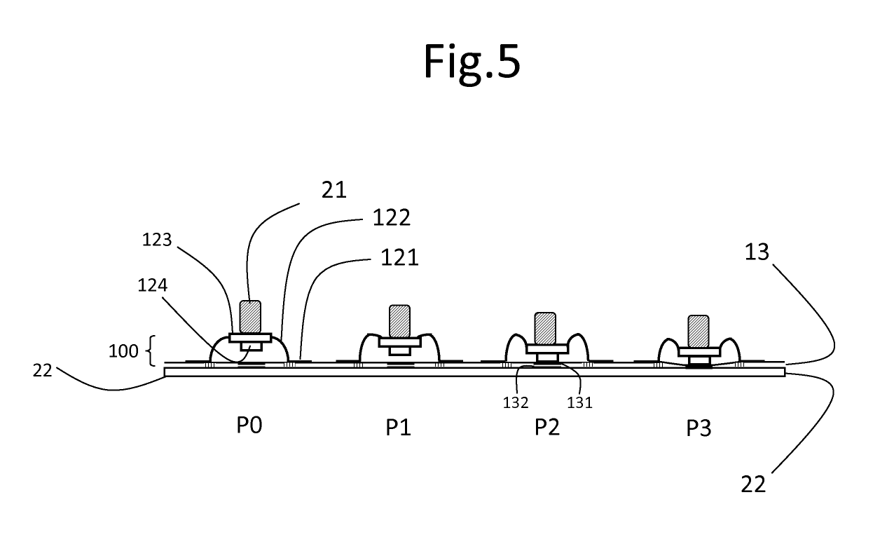

FIG. 5 is the status for the dome switch during test according to the present invention

FIG. 5 shows the status for the dome switch 100 under test. The initial status P0 shows a push rod 21 applying a pressure against the dome top 123 of the dome switch 100; initially the pressure is transmitted to the pressure sensor 22 through the dome wall 122. The pressure sensor 22 senses the pressure coming from the dome wall 122. The collapse status P1 shows the dome switch 100 snaps to restorably collapse. The pressure is sensed by the pressure sensor 22. The contact status P2 shows the bottom 124 of the dome top 123 touches the membrane switch 13, at this moment, the pressure sensed by the pressure sensor 22 increases as the push rod 21 pushes downward. The turn-on status P3 shows the top electrode 131 touches the bottom electrode 132 by the pressure from the bottom 124 of the dome top 123. At this moment, the dome switch 100 is turned on and the pressure sensed by the pressure sensor 22 continues to increase.

FIGS. 6A˜6B are the graphs of physical parameters for the dome switch under test according to the present invention

FIG. 6A is the Force versus Key Journey.

FIG. 6A shows Force Sensed by Pressure Sensor 22 in the Y-coordinate and the Key Journey in the X-coordinate. The top curve PC shows the force sensed by the pressure sensor 22 in the course of increasing pressure against the dome switch 100, i.e. from status P0 to P1, P2, until status P3. The bottom curve RC shows the force sensed by the pressure sensor 22 in the course of pressure releasing from the dome switch 100, i.e. from status P3 to P2, P1, until status P0.

A maximum force exerted between the initial status P0 and the collapse status P1 is termed as Actuation Force (AF). A minimum force exerted between the collapse status P1 and the contact status P2 is termed as Contact Force (CF). The force is applied increasingly to cause the dome switch 100 turn-on after the contact status P2; the minimum force needed to turn on the switch is termed as On Force (OF). FIG. 6A shows the AF occurs at a point between status P0 and P1, at a timing T1; CF occurs at a point between status P1 and P2, at a timing T2; and OF occurs between status P2 and P3.

FIG. 6B is Switch Conductivity versus the Key Journey.

FIG. 6B shows the Switch conductivity in the Y-coordinate and the Key Journey in the X-coordinate. At the moment of OF, the conductivity sharply increases, e.g. from zero until above 5e-3 mho. The dome switch 100 is turned on at this moment.

A term of Snap-Ratio 251 is further defined as one of the physical parameters for the dome switch 100, and calculated according to a mathematical equation as follows:

Snap Ratio=[(AF−CF)/AF]*100%.

In a condition where if the push rod 21 is controlled to move with a constant speed (SP) against the dome switch 100, a term of Key Journey, a distance between the bottom surface 124 and the top surface of the membrane switch 13, is further defined and calculated according to a mathematical equation as follows:

Key Journey=(T2−T1)*SP

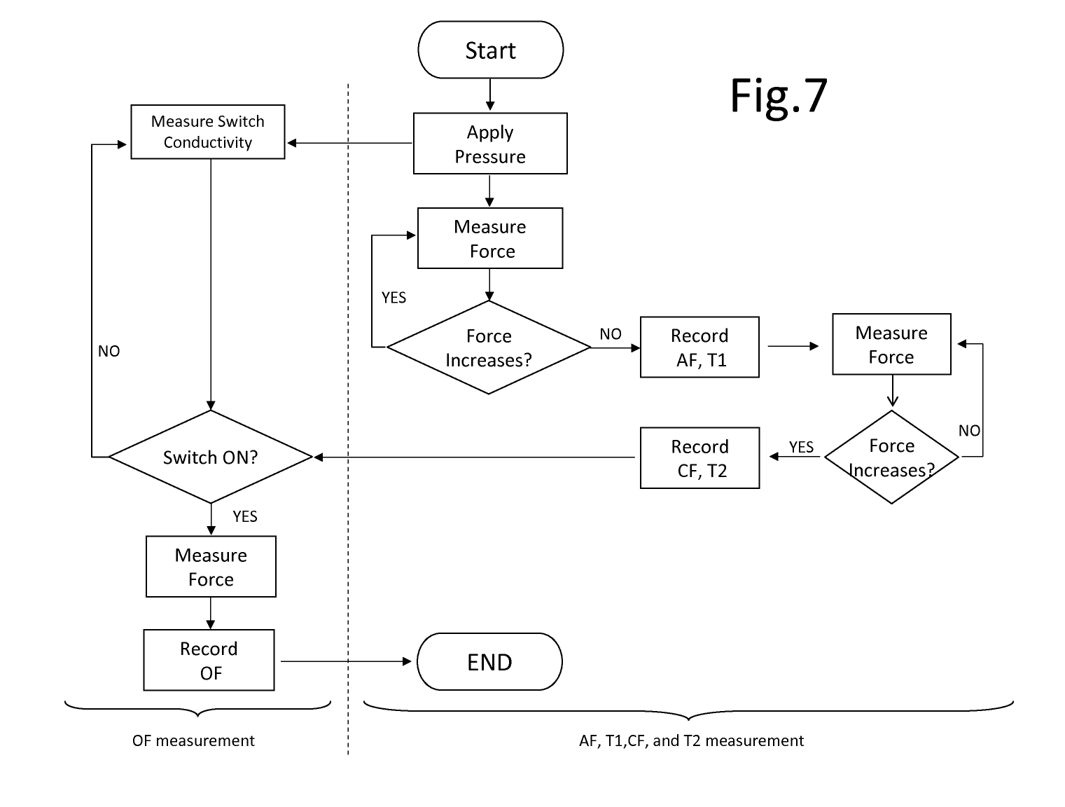

FIG. 7 is an algorithm executable by the first embodiment according to the present invention

In the right section of FIG. 7 where the Actuation Force (AF) and Contact Force (CF) are measured accordingly, the instructions include:

Start;

applying Pressure: the Push Rod 21 moves downward to apply a pressure against the dome switch 100;

measuring Force: the pressure sensor 22 senses the pressure from top;

checking if Force Increases? If YES, go to the previous step; If NO;

recording AF and T1: Actuation Force (AF) is recorded and Timing (T1) is recorded;

measuring Force;

checking if Force Increases? if No, go to the previous step, If YES;

recording CF and T2: Contact Force (CF) is recorded and Timing (T2) is recorded;

END.

The left section of FIG. 7 indicates how the On-Force (OF) is measured according to the instructions:

measuring Switch Conductivity;

checking if Switch ON? If NO, go to the previous step; if YES

measuring force;

recording OF: On-Force is recorded.

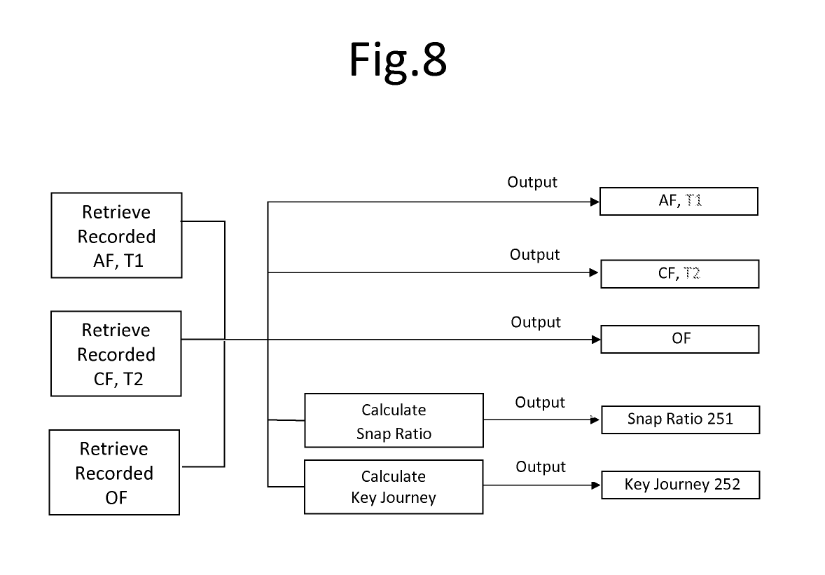

FIG. 8 is a sub-algorithm for data output according to the present invention

FIG. 8 shows instructions to retrieve and output AF, T1, CF, T2 and OF. The sub-algorithm also gives instructions to calculate the Snap Ratio and to output the same. The sub-algorithm also gives instructions to calculate the Key Journey 252 and to output the same.

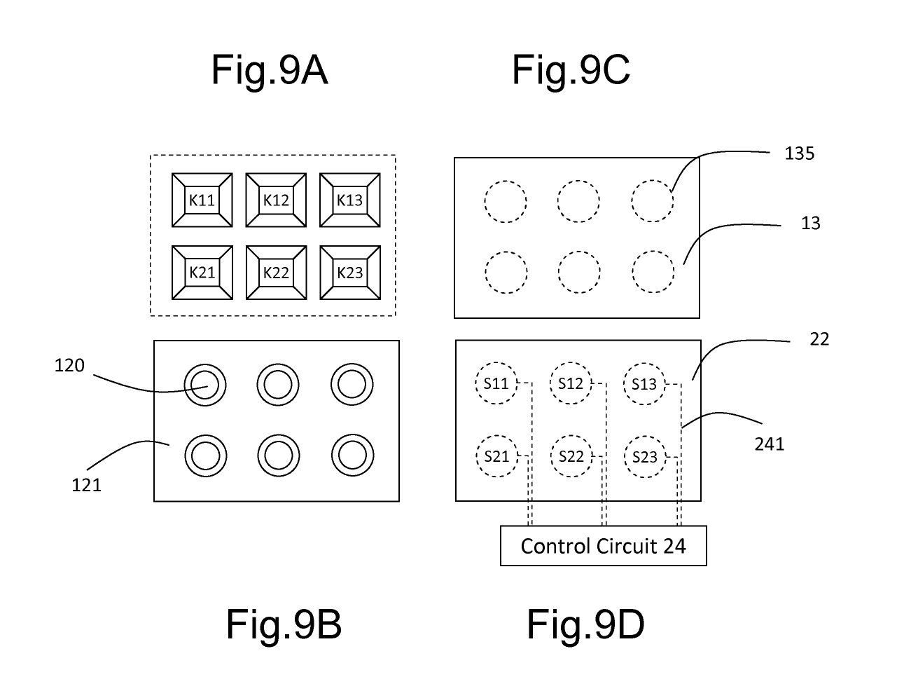

FIGS. 9A˜9D is a key switch array to be tested by the test system according to the present invention.

FIG. 9A shows a key array with key caps K11, K12, K13, K21, K22, and K23.

FIG. 9B shows a dome array with dome units 120 configured on a dome base 121. The dome array is then configured under the key array.

FIG. 9C shows a switch array with switch units 135 configured on a flexible membrane switch 13. The switch array is then configured under the dome array.

FIG. 9D shows a sensor array with sensor units S11, S12, S13, S21, S22, and S23 configured on a sensor substrate 22. The sensor array is then configured under the switch array.

Each of the sensor units S11˜S23 matches with one of the switch units 135, dome units 120, and key caps K11˜K23. The control circuit 24 has a circuitry electrically coupled to each of the sensor units through one of the circuits 241. The control circuit 24 has another circuitry electrically coupled to each of the switch units 135 (not shown in FIG. 9). The control system 24 is able to detect a force selected from a group consisted of Actuation Force (AF), Timing T1, Contact Force (CF), Timing T2, On-Force (OF), Snap Ratio, and Key Journey. The keys can be tested serially or simultaneously.

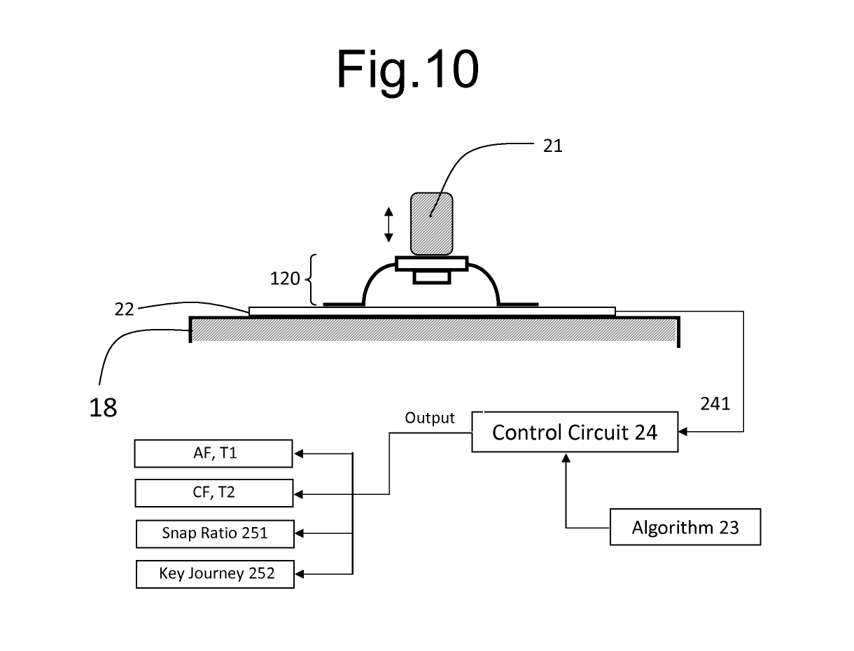

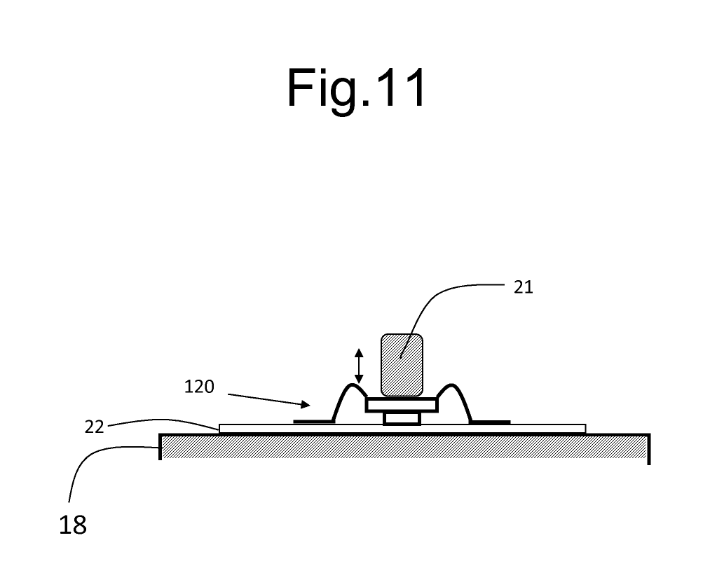

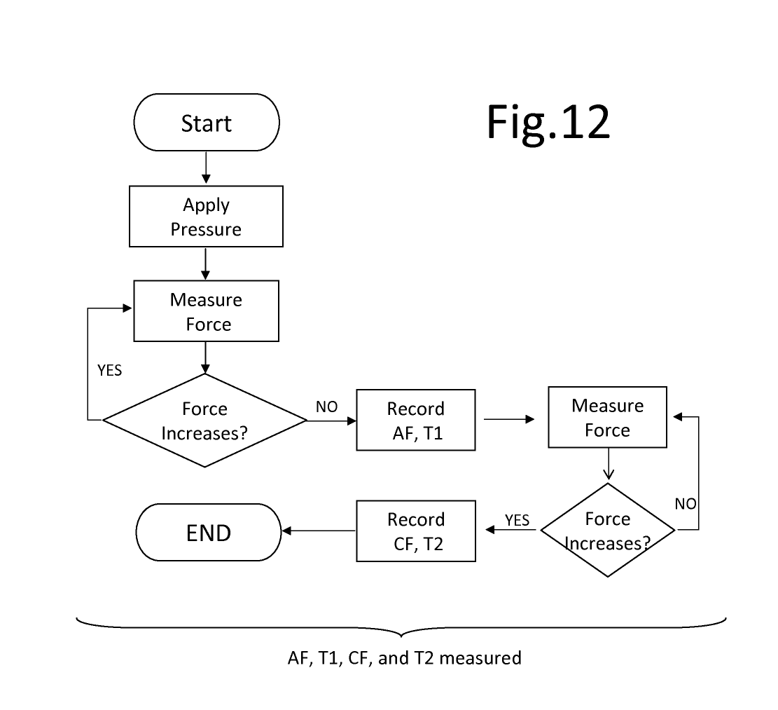

FIGS. 10˜12 is a second embodiment according to the present invention.

FIG. 10 shows initial status for a rubber dome without a membrane switch underneath; and FIG. 11 shows a collapse status for the rubber dome. The rationale for this embodiment is the same as that described above and hence, AF, T1, and CF, T2 can be obtained through the present invention. The Snap Ratio, calculated by AF and CF, is therefore obtained. The Key Journey, calculated by T1 and T2, is also obtained.

FIG. 12 shows an algorithm executable by the second embodiment

FIG. 12 is an algorithm executable by the second embodiment according to the present invention. The instructions include:

Start;

applying Pressure: the Push Rod 21 moves downward to apply a pressure against the rubber dome 120;

measuring Force: the pressure sensor 22 senses the pressure from top;

checking if Force Increases? If YES, go to the previous step; If NO;

recording AF and T1: Actuation Force (AF) is recorded and Timing (T1) is recorded;

measuring Force;

checking if Force Increases? If NO, go to the previous step; if YES;

recording CF and T2: Contact Force (CF) is recorded and Timing (T2) is recorded;

END.

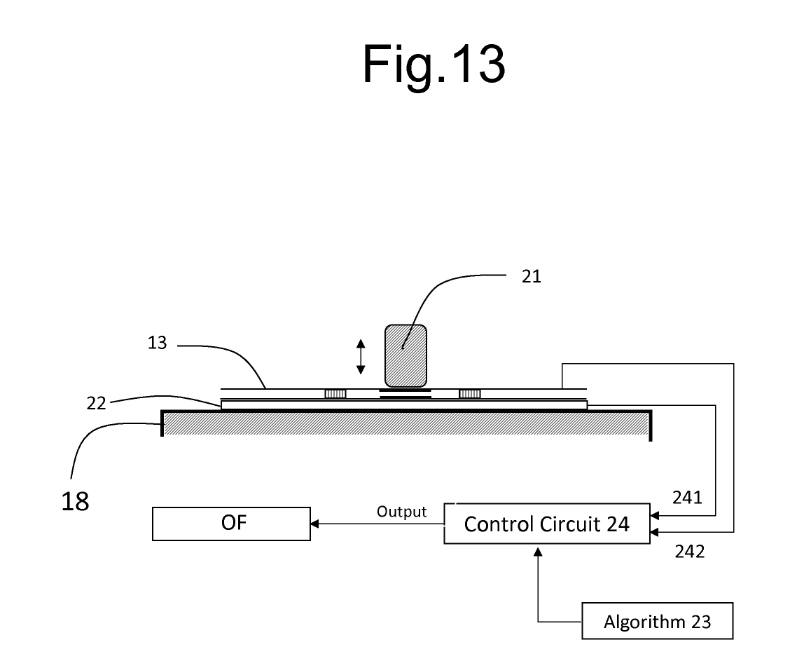

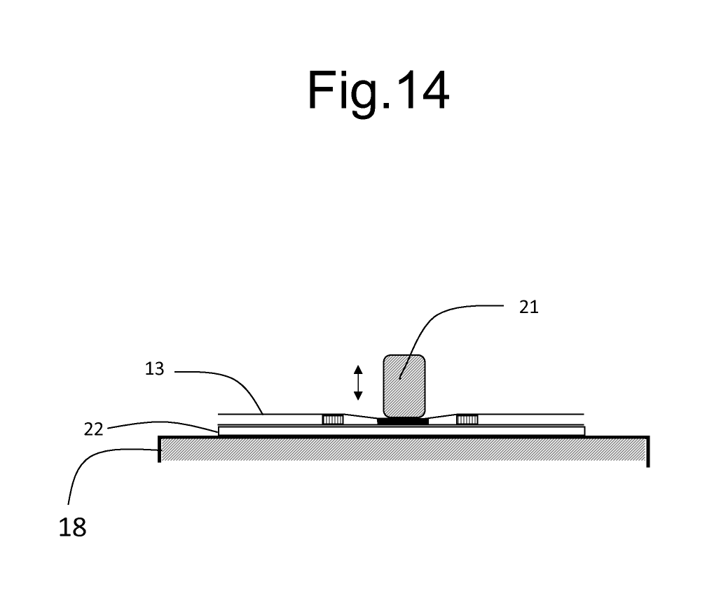

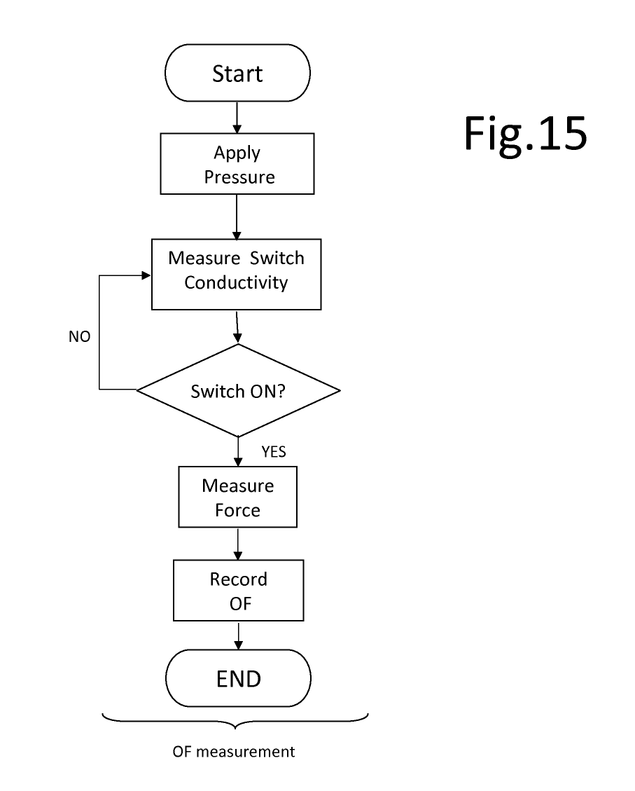

FIGS. 13˜15 is a third embodiment according to the present invention.

FIG. 13 shows initial status for the membrane switch 13 and FIG. 14 shows a contact status for the membrane switch 13. The rationale for this embodiment is the same as that described above, however only OF is significantly obtained through the present invention.

FIG. 15 is an algorithm executable by the third embodiment according to the present invention. The instructions include:

Start;

applying Pressure: the Push Rod 21 moves downward to apply a pressure against the membrane switch 13;

measuring Switch Conductivity;

checking if Switch ON? If NO, go to the previous step; If YES;

measuring Force: the pressure sensor 22 senses the pressure from top;

recording OF: ON Force (OF) is recorded;

END.

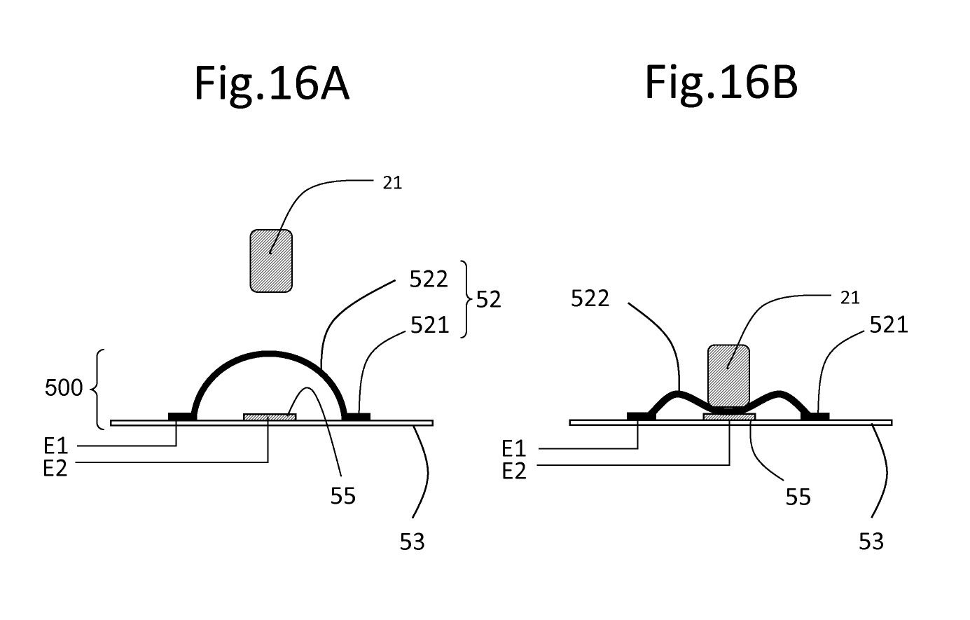

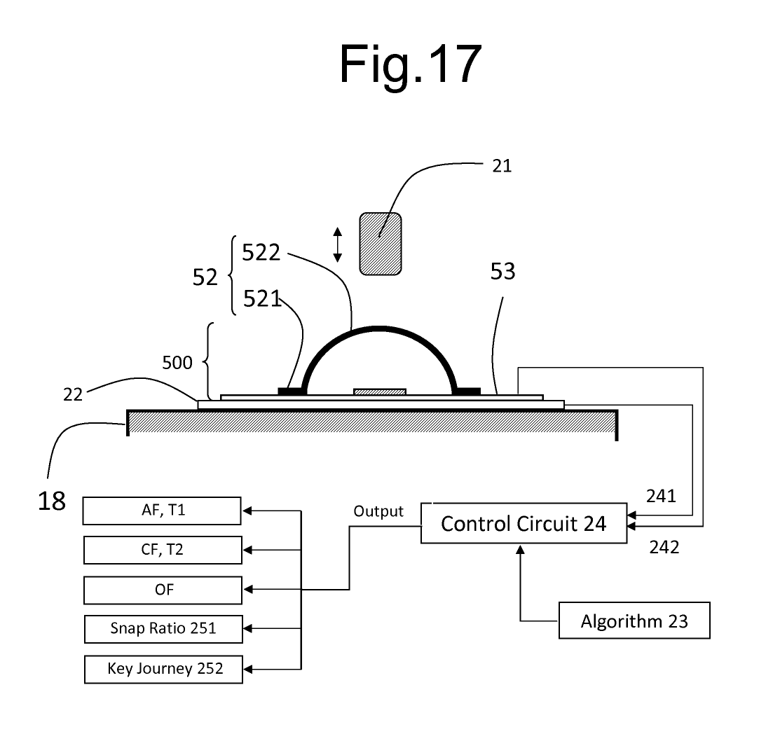

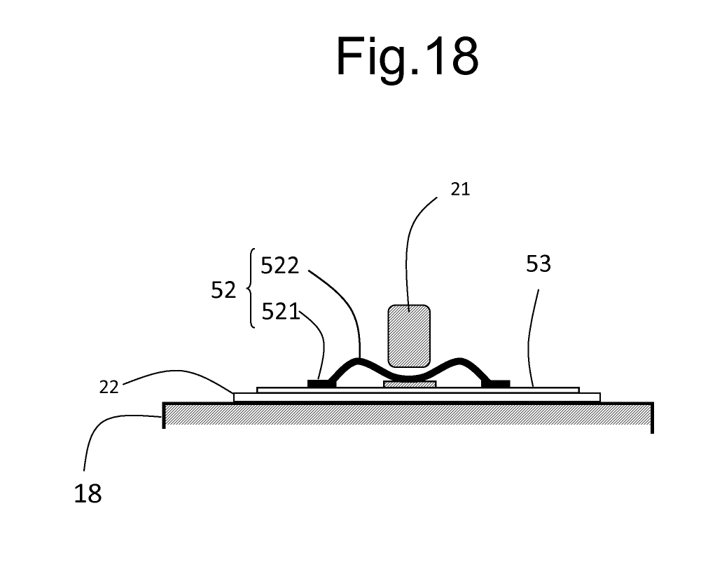

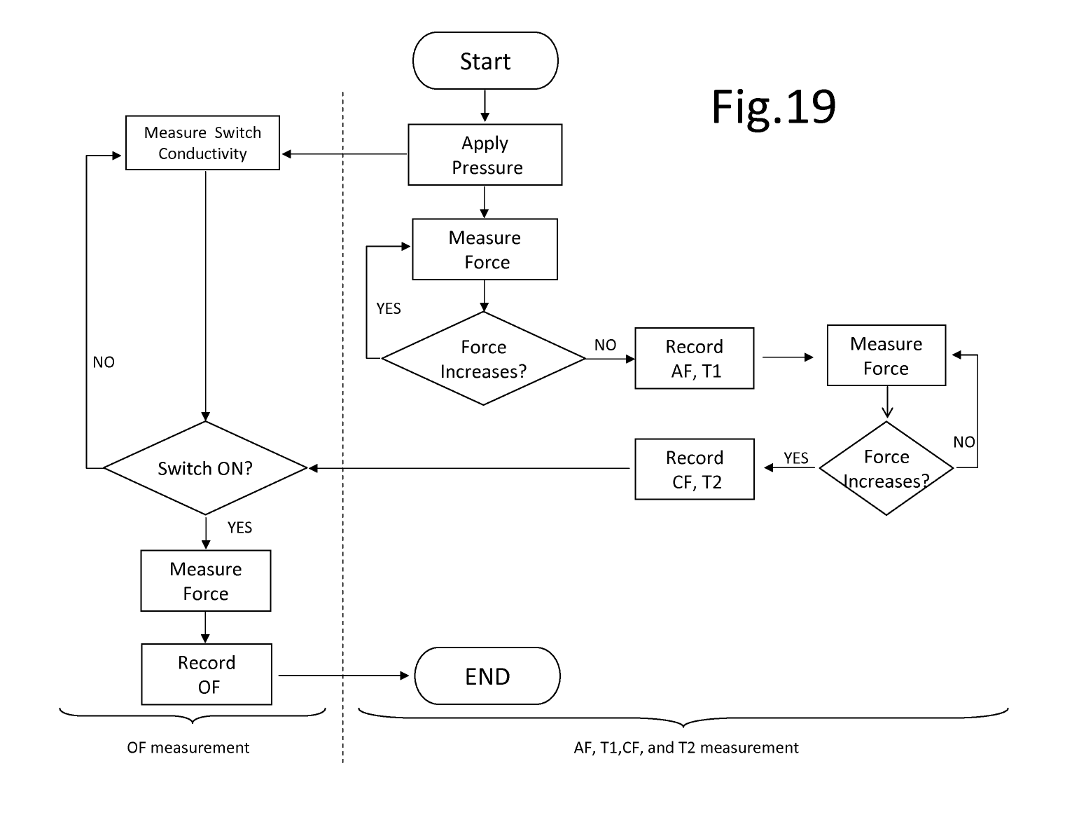

FIGS. 16˜19 show a fourth embodiment according to the present invention

FIG. 16A shows a metal dome switch 500 which is also applicable to be tested by the test system according to the present invention. The metal dome switch 500 includes a metal dome 52 and a circuit board 50. The metal dome 52 has a dome base 521 and a metal dome wall 522, configured on a top surface of the circuit board 53. The circuit board 53 has a circuitry (not shown) thereon to electrically coupled to the metal dome 52. The dome base 521 is electrically coupled to a first electrode E1 of the control circuit 24. A metal contact 55 is made on a top surface of the circuit board 53. The metal contact 55 is configured in an area under the dome wall 522 which is actually a dome cup, and configured electrically coupled to a second electrode E2 of the control circuit 24. The metal contact 55 is configured electrically isolated from the metal dome 52, before the metal dome 52 collapses and shorts with the metal contact 55.

FIG. 16B shows a collapse status of the metal dome 52 after a pressure is applied against the metal dome 52 by the simple push rod 21; at this moment, the collapsed dome wall 522 contacts the metal contact 55, and then the metal dome switch 500 displays a turn-on status.

FIG. 17 is a metal dome switch tested in a test system according to the present invention

FIG. 17 shows a test system for testing a metal dome switch 500. The system has a film type pressure sensor 22 which provides a top surface for carrying the metal dome switch 500 to be tested. A platform 18 is provided for carrying the film type pressure sensor 22. A control circuit 24 has a first end 241 electrically coupled to the film type pressure sensor 22 for sensing pressure coming from top. The control circuit 24 has a second end 242 electrically coupled to the circuit board 53 of the metal dome switch 500. The control circuit 24 is able to detect a physical parameter selected from a group consisted of Actuation Force (AF), Timing T1, Contact Force (CF), Timing T2, and On-Force (OF), for the metal dome switch 500 when a pressure is applied onto the metal dome switch 500. A simple push rod 21 is configured above the metal dome switch 500 for providing such a pressure downward against the metal dome switch 500. An algorithm 23 is executed by control circuit 24 for the testing process. At least one of the physical parameters consisted of AF, T1, CF, T2, OF, Snap Ratio 251 and Key Journey 252, is output from the test system. In this case, the OF is equal to CF.

FIG. 18 shows a collapse status of the metal dome switch 500 after a pressure is applied against the metal dome 52 by the simple push rod 21; at this moment, the collapsed dome wall 522 contacts the metal contact 55, and then the metal dome switch 500 displays a turn-on status.

FIG. 19 is an algorithm executable by the fourth embodiment according to the present invention

FIG. 19 shows the algorithm for the control circuit 24. In the right section of FIG. 19 where the Actuation Force (AF), Timing T1, and Contact Force (CF), Timing T2 are measured accordingly, the instructions include:

Start;

applying Pressure: the Push Rod 21 moves downward to apply a pressure against the metal dome switch 500;

measuring Force: the pressure sensor 22 senses the pressure from top;

checking if Force Increases? If YES, go to the previous step; If NO;

recording AF and T1: Actuation Force (AF) is recorded and Timing (T1) is recorded;

measuring Force;

checking if Force Increases? If no, go to the previous step; if YES

recording CF and T2: Contact Force (CF) is recorded and Timing (T2) is recorded.

The left section of FIG. 19 indicates how the On-Force (OF) is measured according to the instructions:

measuring Switch Conductivity;

checking if Switch ON? If NO, go to the previous step; if YES

measuring force;

recording OF: On-Force is recorded;

END.

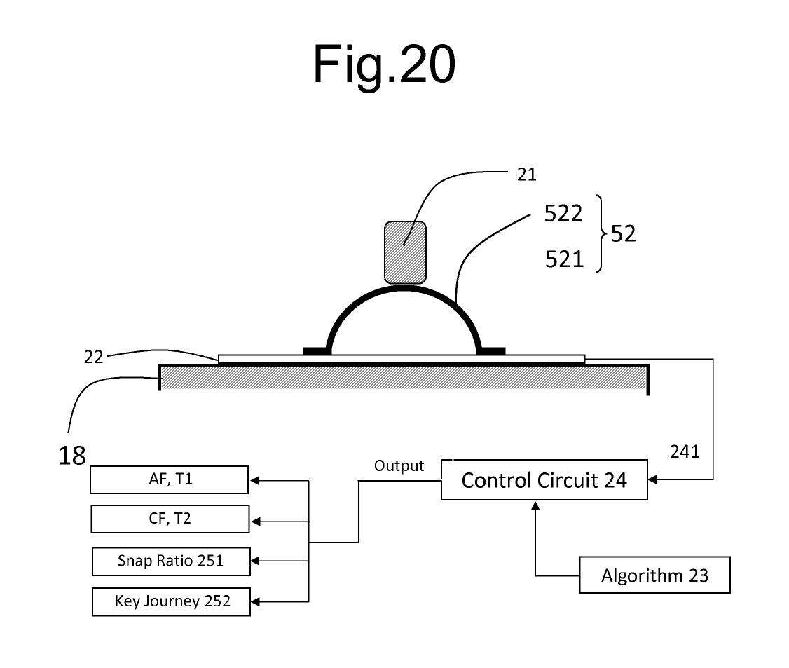

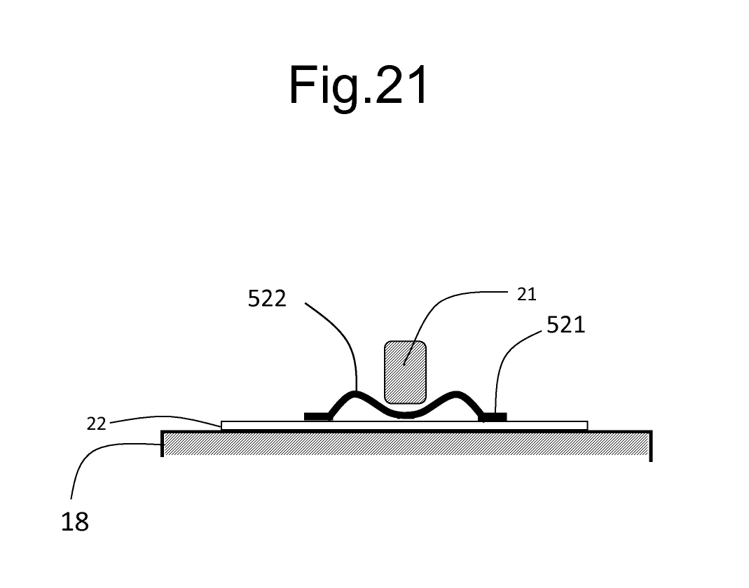

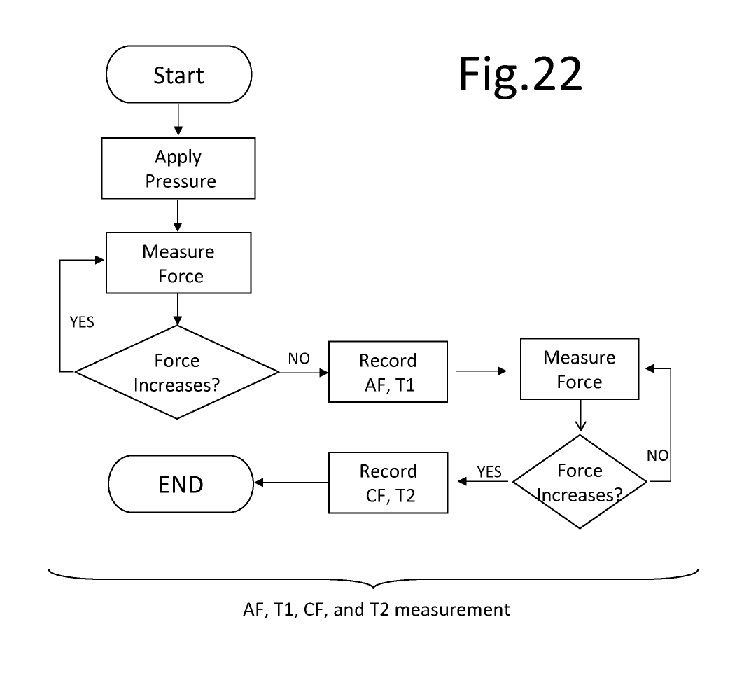

FIGS. 20˜22 is a fifth embodiment according to the present invention

FIG. 20 shows initial status for a simple metal dome 52 without a circuit board underneath to be tested. A pressure sensor 22 is configured under the simple metal dome 52 to sense the forces coming from top. A platform 18 is configured under the pressure sensor 22. FIG. 21 shows a collapse status for the metal dome 52. The rationale for this embodiment is the same as that described above and hence, AF, T1, and CF, T2 can be obtained through the present invention. The Snap Ratio, calculated by AF and CF, is therefore obtained. The Key Journey, calculated by T1 and T2, is also obtained.

FIG. 22 is an algorithm executable by the fifth embodiment according to the present invention. The instructions include:

Start;

applying Pressure: the Push Rod 21 moves downward to apply a pressure against the rubber dome 120;

measuring Force: the pressure sensor 22 senses the pressure from top;

checking if Force Increases? If YES, repeat the previous step; If NO;

recording AF and T1: Actuation Force (AF) is recorded and Timing (T1) is recorded;

measuring Force;

checking if Force Increases? If NO, go to the previous step; if YES;

recording CF and T2: Contact Force (CF) is recorded and Timing (T2) is recorded;

END.

The film type pressure sensor 22 for the test system is selected from a group consisted of a piezoresistive pressure sensor, a piezoelectric pressure sensor, and a piezo-capacitive pressure sensor.

While several embodiments have been described by way of example, it will be apparent to those skilled in the art that various modifications may be configured without departing from the spirit of the present invention. Such modifications are all within the scope of the present invention, as defined by the appended claims.

What is claimed is:

1. A test system for a dome switch, comprising:
a film type pressure sensor; providing a top surface for carrying the dome switch to be tested; and
a control circuit, having a first end electrically coupled to the film type pressure sensor; having a second end electrically coupled to the dome switch; being able to detect a physical parameter selected from a group consisted of Actuation Force (AF), Timing T1, Contact Force (CF), Timing T2, On-Force (OF), Snap Ratio, and Key Journey, of the dome switch when a pressure is applied over the dome switch.

2. A test system for a dome switch as claimed in claim 1, wherein the dome switch is selected from a group consisted of rubber dome switch and metal dome switch.

3. A test system for a dome switch as claimed in claim 1, wherein the dome of the switch is selected from a group consisted of rubber dome and metal dome.

4. A test system for a rubber dome switch, comprising:
a film type pressure sensor; providing a top surface for carrying the rubber dome switch to be tested; and
a control circuit, having a first end electrically coupled to the film type pressure sensor; having a second end electrically coupled to the dome switch; being able to detect a physical parameter selected from a group consisted of Actuation Force (AF), Timing T1, Contact Force (CF), Timing T2, On-Force (OF), Snap Ratio, and Key Journey, of the dome switch when a pressure is applied over the dome switch.

5. A test system for a rubber dome switch as claimed in claim 4, wherein the Snap-Ratio is calculated according to a mathematical equation as follows:
Snap Ratio=[(AF−CF)/AF]*100%.

6. A test system for a rubber dome switch as claimed in claim 4, wherein the pressure is applied with a constant speed (SP) against the dome switch.

7. A test system for a rubber dome switch as claimed in claim 4, wherein the first timing (T1) is defined a moment of an occurrence of the actuation force (AF); and the second timing (T2) is defined a moment of an occurrence of the contact force (CF).

8. A test system for a rubber dome switch as claimed in claim 7, wherein the Key Journey is calculated according to a mathematical equation as follows:
Key Journey=(T2−T1)*SP

9. A test system for a rubber dome switch as claimed in claim 5, wherein the control circuit further comprises a function to output the Snap Ratio.

10. A test system for a rubber dome switch as claimed in claim 8, wherein the control circuit further comprises a function to output the Key Journey.

11. A test system for a rubber dome switch as claimed in claim 4, wherein the control circuit further comprises a function to output a physical parameter selected from a group consisted of Actuation Force (AF), Timing T1, Contact Force (CF), Timing T2, and On-Force (OF).

12. A test system for a rubber dome switch as claimed in claim 4, further comprising:
an algorithm to be executed by the control circuit, further comprising:
an instruction to detect a physical parameter selected from a group consisted of Actuation Force (AF), Timing T1, Contact Force (CF), Timing T2, On-Force (OF), Snap Ratio, and Key Journey.

13. A test system for a rubber dome switch as claimed in claim 12, wherein the first timing (T1) is defined a moment of an occurrence of the actuation force (AF), and the second timing (T2) is defined a moment of an occurrence of the contact force (CF).

14. A test system for a rubber dome switch as claimed in claim 13, wherein the Snap-Ratio is calculated according to a mathematical equation as follows:
Snap Ratio=[(AF−CF)/AF]*100%.

15. A test system for a rubber dome switch as claimed in claim 13, wherein the Key Journey is calculated according to a mathematical equation as follows:
Key Journey=(T2−T1)*SP

16. A test system for a rubber dome switch as claimed in claim 14, wherein the algorithm further comprises an instruction to output the Snap Ratio.

17. A test system for a rubber dome switch as claimed in claim 15, wherein the algorithm further comprises an instruction to output the Key Journey.

18. A test system for a rubber dome switch as claimed in claim 12, wherein the algorithm further comprises an instruction to output a physical parameter selected from a group consisted of Actuation Force (AF), Timing T1, Contact Force (CF), Timing T2, ON Force (OF), Snap Ratio, and Key Journey.

19. A test system for a rubber dome switch as claimed in claim 4, wherein the film type pressure sensor is selected from a group consisted of a piezoresistive pressure sensor, a piezoelectric pressure sensor, and a piezo-capacitive pressure sensor.

20. An algorithm to be executed by the control circuit as claimed in claim 4, comprising:
applying Pressure;
measuring Force;
checking if Force Increases? if NO:
recording at least one of AF and T1: Actuation Force (AF) and Timing (T1) selectively or both recorded;
measuring Force; and
checking if Force Increases? if YES
recording at least one of CF and T2: Contact Force (CF) and Timing (T2) selectively or both recorded.

21. An algorithm to be executed by the control circuit as claimed in claim 20, further comprising:
measuring Conductivity; and
checking if Switch ON? if YES
measuring force;
recording OF: On-Force (OF) is recorded.

22. A test system for testing an array of dome switch, comprising:
a film type pressure sensor, having an array of sensor units; providing a top surface for carrying the array of dome switch to be tested; and
a control circuit, electrically coupled to each of the sensor units, being able to detect a physical parameter selected from a group consisted of Actuation Force (AF), Timing T1, Contact Force (CF), Timing T2, On-Force (OF), Snap Ratio, and Key Journey, of each of the keys when a test pressure is applied.

23. A test system for testing a simple rubber dome, comprising:
a film type pressure sensor; providing a top surface for carrying the dome to be tested; and
a control circuit, electrically coupled to the film type pressure sensor; being able to detect a physical parameter selected from a group consisted of Actuation Force (AF), Timing T1, Contact Force (CF), Timing T2, Snap Ratio, and Key Journey, of the dome when a pressure is applied over the dome.

24. An algorithm to be executed by the control circuit as claimed in claim 23, comprising:
applying Pressure;
measuring Force;
checking if Force Increases? if NO:
recording at least one of AF and T1: Actuation Force (AF) and Timing (T1) selectively or both recorded;
measuring Force; and
checking if Force Increases? if YES;
recording at least one of CF and T2: Contact Force (CF) and Timing (T2) selectively or both recorded.

25. A test system for testing a membrane switch, comprising:
a film type pressure sensor; providing a top surface for carrying the membrane switch to be tested; and
a control circuit, having a first end electrically coupled to the film type pressure sensor; having a second end electrically coupled to the membrane switch; being able to detect an ON-Force (OF) of the membrane switch when a test pressure is applied.

26. An algorithm to be executed by the control circuit as claimed in claim 25, comprising:
applying Pressure;
measuring Switch Conductivity;
checking if the Switch On? if YES
measuring force;
recording OF; ON-Force (OF) is recorded.

27. A test system for a metal dome switch, comprising:
a film type pressure sensor; providing a top surface for carrying the dome switch to be tested; and
a control circuit, having a first end electrically coupled to the film type pressure sensor; having a second end electrically coupled to the dome switch; being able to detect a physical parameter selected from a group consisted of Actuation Force (AF), Timing T1, Contact Force (CF), Timing T2, and On-Force (OF), of the dome switch when a pressure is applied over the dome switch.

28. A test system for a dome switch as claimed in claim 27, wherein the Snap-Ratio is calculated according to a mathematical equation as follows:
Snap Ratio=[(AF−CF)/AF]*100%.

29. A test system for a metal dome switch as claimed in claim 27, wherein the pressure is applied with a constant speed (SP) against the dome switch.

30. A test system for a metal dome switch as claimed in claim 27, wherein the first timing (T1) is defined a moment of an occurrence of the actuation force (AF); and the second timing (T2) is defined a moment of an occurrence of the contact force (CF).

31. A test system for a metal dome switch as claimed in claim 30, wherein the Key Journey is calculated according to a mathematical equation as follows:
Key Journey=(T2−T1)*SP

32. A test system for a metal dome switch as claimed in claim 28, wherein the control circuit further comprises a function to output the Snap Ratio.

33. A test system for a metal dome switch as claimed in claim 31, wherein the control circuit further comprises a function to output the Key Journey.

34. A test system for a metal dome switch as claimed in claim 27, wherein the control circuit further comprises a function to output a physical parameter selected from a group consisted of Actuation Force (AF), Timing T1, Contact Force (CF), Timing T2 and ON-Force (OF).

35. A test system for a metal dome switch as claimed in claim 27, further comprising:
an algorithm to be executed by the control circuit, further comprising:
an instruction to detect a physical parameter selected from a group consisted of Actuation Force (AF), Timing T1, Contact Force (CF), Timing T2, On-Force (OF), Snap Ratio and Key Journey.

36. A test system for a metal dome switch as claimed in claim 35, wherein the first timing (T1) is defined a moment of an occurrence of the actuation force (AF), and the second timing (T2) is defined a moment of an occurrence of the contact force (CF).

37. A test system for a metal dome switch as claimed in claim 36, wherein the Snap-Ratio is calculated according to a mathematical equation as follows:
Snap Ratio=[(AF−CF)/AF]*100%.

38. A test system for a metal dome switch as claimed in claim 36, wherein the Key Journey is calculated according to a mathematical equation as follows:
Key Journey=(T2−T1)*SP

39. A test system for a metal dome switch as claimed in claim 37, wherein the algorithm further comprises an instruction to output the Snap Ratio.

40. A test system for a metal dome switch as claimed in claim 38, wherein the algorithm further comprises an instruction to output the Key Journey.

41. A test system for a metal dome switch as claimed in claim 35, wherein the algorithm further comprises an instruction to output a physical parameter selected from a group consisted of Actuation Force (AF), Timing T1, Contact Force (CF), Timing T2, and ON Force (OF).

42. A test system for a metal dome switch as claimed in claim 27, wherein the film type pressure sensor is selected from a group consisted of a piezoresistive pressure sensor, a piezoelectric pressure sensor, and a piezo-capacitive pressure sensor.

43. An algorithm to be executed by the control circuit as claimed in claim 27, comprising:
applying Pressure;
measuring Force;
checking if Force Increases? if NO:
recording at least one of AF and T1: Actuation Force (AF) and Timing (T1) selectively or both recorded;
measuring Force; and
checking if Force Increases? if YES;
recording at least one of CF and T2: Contact Force (CF) and Timing (T2) selectively or both recorded.

44. An algorithm to be executed by the control circuit as claimed in claim 43, further comprising:
measuring Conductivity;
checking if Switch ON? if YES
measuring force;
recording OF: On-Force is recorded.

45. A test system for testing a simple metal dome, comprising:
a film type pressure sensor; providing a top surface for carrying the dome to be tested; and
a control circuit, electrically coupled to the film type pressure sensor; being able to detect a physical parameter selected from a group consisted of Actuation Force (AF), Timing T1, Contact Force (CF), Timing T2, Snap Ratio, and Key Journey, of the dome when a pressure is applied over the dome.

46. An algorithm to be executed by the control circuit as claimed in claim 45, comprising:
applying Pressure;
measuring Force;
checking if Force Increases? If NO:
recording at least one of AF and T1: Actuation Force (AF) and Timing (T1) selectively or both recorded;
measuring Force; and
checking if Force Increases? if YES;
Recording at least one of CF and T2: Contact Force (CF) and Timing (T2) selectively or both recorded.
